(19) United States
(12) Patent Application Publication
(10) Pub. No.: US 2010/0142158 A1
(43) Pub. Date: Jun. 10, 2010

(54) ELECTRONIC DEVICE

(75) Inventors: LEE-HAN NG, Shenzhen City (CN); LUCAS HUANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignee: FIH (Hong Kong) Limited, Kowloon (HK)

(21) Appl. No.: 12/393,561

(22) Filed: Feb. 26, 2009

(30) Foreign Application Priority Data
Dec. 10, 2008 (CN) 200810306082.7

(51) Int. Cl. H05K 5/02; H05K 7/00

(52) U.S. Cl. 361/737

(57) ABSTRACT

An electronic device is described. The electronic device includes a body member defining a receiving cavity, a chip card received in the receiving cavity and a cover member. The cover member is slidably mounted to the body member and capable of opening or closing the receiving cavity.

### BACKGROUND

1. Technical Field

The present disclosure relates to electronic devices and, particularly, to an electronic device.

2. Description of related art

Electronic devices such as mobile phones typically have chip cards (e.g., subscriber identity module cards) for storing useful information. Chip card holders are used to hold/secure the chip cards within the electronic devices. A typical chip card holder is defined inside a battery receiving compartment. A user must first remove the battery then take out the chip card from the chip card holder, which is tedious and requires powering down the electronic device.

Therefore, there is room for improvement within the art.

### BRIEF DESCRIPTION OF THE DRAWINGS

Many aspects of the electronic device can be better understood with reference to the following drawings. These drawings are not necessarily drawn to scale, the emphasis instead being placed upon clearly illustrating the principles of the present electronic device. Moreover, in the drawings like reference numerals designate corresponding sections throughout the several views.

FIG. 1 is an isometric view of An electronic device, in accordance with an exemplary embodiment.

FIG. 2 is a first state of the electronic device, shown in FIG. 1.

FIG. 3 is a second state of the electronic device, shown in FIG. 1.

### DETAILED DESCRIPTION OF EXEMPLARY EMBODIMENT

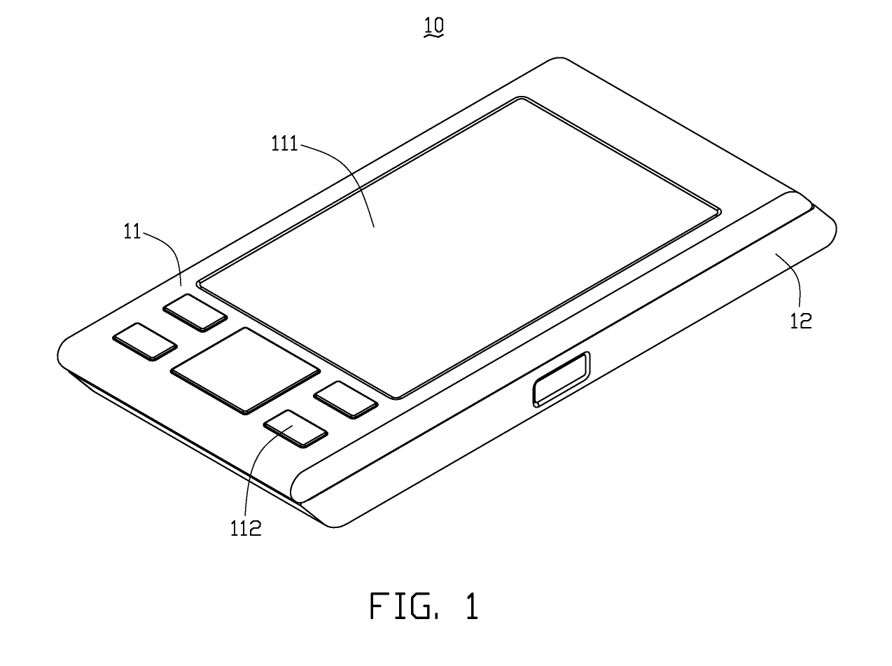

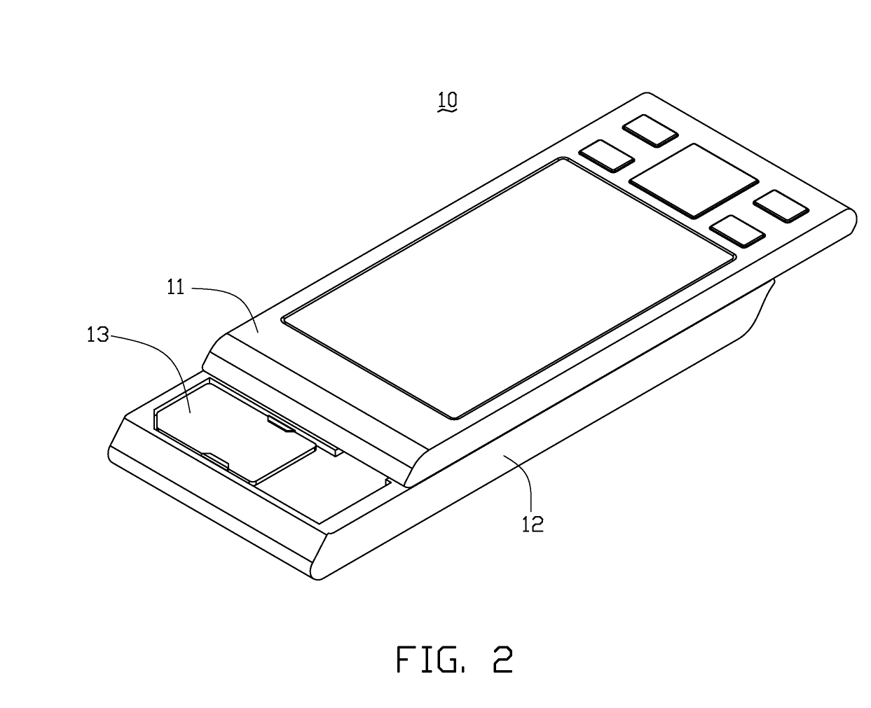

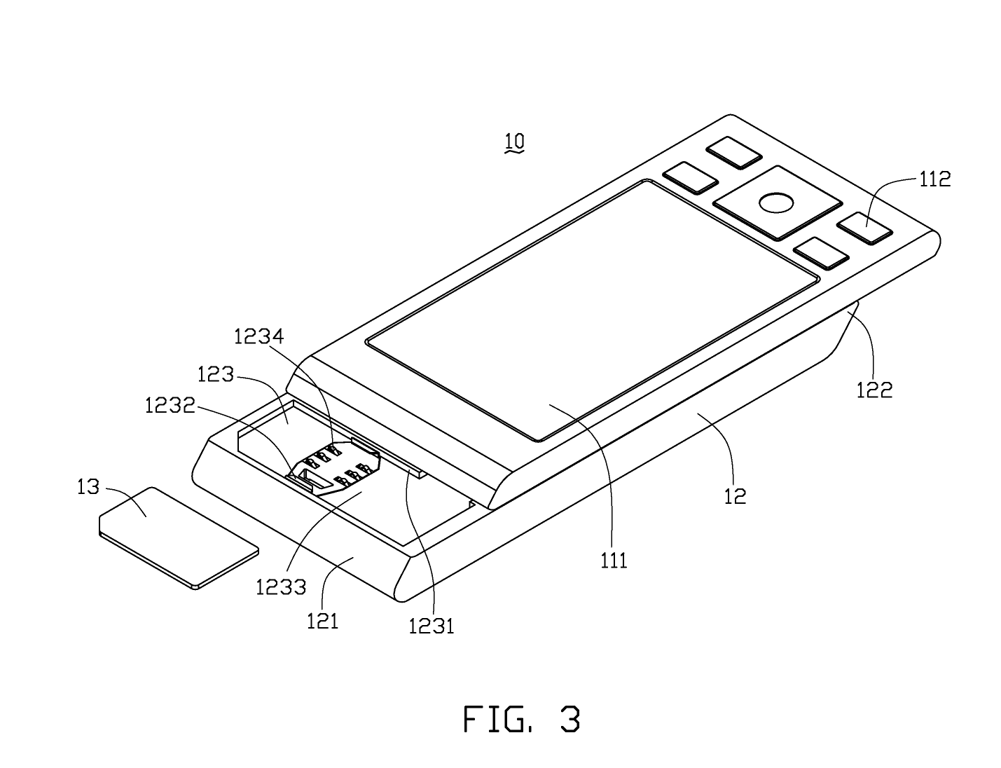

FIGS. 1 through 3 show an exemplary electronic device 10 including a cover member 11, a body member 12, and a chip card 13 (e.g., subscriber identity model card). The cover member 11 is slidably mounted to the body member 12. The chip card 13 is received in the body member 12 and shielded by the cover member 11.

The cover member 11 is a generally thin and sheet-shaped. The cover member 11 defines a display 111 and a plurality of buttons 112 adjacent to the display 111.

The body member 12 is also generally thin and sheet-shaped. The body member 12 includes a top end 121 and an opposite bottom end 122. The body member 12 defines a receiving cavity 123 adjacent to the top end 121. Two limiting blocks 1232 protrude from two opposite sidewalls 1231 of the receiving cavity 123 with a bottom wall 1233. A plurality of elastic connecting poles 1234 is disposed on the bottom wall 1233. The cover member 11 is slidably mounted to the body member 12 to expose or close off the receiving cavity 123.

The chip card 13 is a SIM card in the exemplary embodiment. The receiving cavity 123 is configured to receive the SIM card 13. At this time, the SIM card 13 is tightly latched by the two limiting blocks 1232 and electrically contacts the elastic connecting poles 1234.

To replace the SIM card 13, slide the cover member 11 towards the bottom end 122 of the body member 12 until the receiving cavity 123 is exposed. At this stage, a user can easily take out the SIM card 13.

The cover member 11 slides relative to the body member 12 to open or close the receiving cavity 123, thus it is convenient to replace the chip card 13, avoiding cutting off the power of the electronic device 10.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of sections within the principles of the invention to the full extent indicated by the broad general meaning of the terms, in which the appended claims are expressed.

What is claimed is:

1. An electronic device, comprising:
a body member defining a receiving cavity;
a chip card removably received in the receiving cavity; and
a cover member slidably mounted to the body member; wherein the cover is cable of sliding between an open and a closed position.

2. The electronic device as claimed in claim 1, wherein two limiting blocks protrude from two opposite sidewalls of the receiving cavity, the limiting blocks are capable of securing the chip card.

3. The electronic device as claimed in claim 1, wherein a bottom wall of the receiving cavity has a plurality of elastic connecting poles, the elastic connecting poles contact the chip card.

4. The electronic device as claimed in claim 1, wherein the chip card is a subscriber identity module card.

5. The electronic device as claimed in claim 1, wherein the cover member comprises of a display and a plurality of buttons.

6. A chip card holder used to hold a chip card therein, comprising:
a body member defining a receiving cavity, the chip card being removably received in the receiving cavity; and
a cover member slidably mounted to the body member;
wherein the cover is cable of sliding between an open and a closed position.

7. The chip card holder as claimed in claim 6, wherein the body member is a housing of an electronic device, and the cover member is another housing of the electronic device.

8. The chip card holder as claimed in claim 6, wherein two limiting blocks protrude from two opposite sidewalls of the receiving cavity, the limiting blocks are capable of securing the chip card.

9. The chip card holder as claimed in claim 6, wherein a bottom wall of the receiving cavity has a plurality of elastic connecting poles, the elastic connecting poles contact the chip card.

10. The chip card holder as claimed in claim 6, wherein the chip card is a subscriber identity module card.

11. The chip card holder as claimed in claim 6, wherein the cover member comprises of a display and a plurality of buttons.
